(19) United States
(12) Patent Application Publication
(10) Pub. No.: US 2012/0243161 A1
(43) Pub. Date: Sep. 27, 2012

(54) ELECTRONIC DEVICE

(75) Inventors: Yusuke Mizuno, Kawasaki (JP); Naoki Miyakoshi, Kawasaki (JP); Shinya Matsushita, Kawasaki (JP)

(73) Assignee: FUJITSU LIMITED, Kawasaki-shi (JP)

(21) Appl. No.: 13/486,465

(22) Filed: Jun. 1, 2012

Related U.S. Application Data
(63) Continuation of application No. PCT/JP2009/070316, filed on Dec. 3, 2009.

(51) Int. Cl. G06F 1/16; H05K 5/03

(52) U.S. Cl. 361/679.08; 361/679.01; 361/679.37

(57) ABSTRACT

An electronic device includes a housing including an installing part having an opening, an electronic component installed in the installing part and including a first side surface and a second side surface, an attachment component fastened to the electronic component and configured to fix the first side surface to the housing, and a cover component detachably attached to the opening and configured to cover the opening. The cover component includes an elastic member configured to exert force to the vicinity of the second side surface.

### CROSS-REFERENCE TO RELATED APPLICATIONS

This application is a U.S. continuation application filed under 35 USC 111(a) claiming benefit under 35 USC 120 and 365(c) of PCT application JP 2009/070316, filed on Dec. 3, 2009. The foregoing application is hereby incorporated herein by reference.

### FIELD

The embodiments discussed herein are related to an electronic device.

### BACKGROUND

In recent years and continuing, there is a desire for further size reduction and weight reduction of portable type electronic devices such as notebook type personal computers (hereinafter also referred to as “notebook PCs”)). Therefore, many electronic components are installed densely inside a housing of the electronic devices with hardly any space therebetween. A large size electronic component such as a hard disk drive (HDD) may be mounted on the electronic device, namely, for example, a notebook PC.

For example, in a case of mounting the HDD to the notebook PC, an attachment metal fitting is attached to both sides of the HDD or attached in a transverse manner from one side to the other of the HDD. Then, the HDD is installed into an installing part of a housing and has the attachment fitting fastened to the housing with screws. The HDD includes a storage device having a mechanically moveable part. The storage device makes accesses to information in correspondence with the movement of the storage device. Because the HDD accesses information in correspondence with the mechanical movement of the movable part, the life-span of the HDD is relatively short. In installing the HDD into the installing part of the housing, an opening is formed in the installing part, so that the HDD can be installed from the opening. After installing the HDD, the opening may be closed by a lid. The electronic components such as an HDD not only have a large size but also have a large amount of weight (heavy). Therefore, the electronic device including the heavy electronic component tends to use a sturdy, large, and heavy attachment fitting. This results in an increase of size and weight of the electronic device.
Patent Document Japanese Laid-Open Patent Publication No. 2007-328531

### SUMMARY

According to an aspect of the invention, there is provided an electronic device including a housing including an installing part having an opening, an electronic component installed in the installing part and including a first side surface and a second side surface, an attachment component fastened to the electronic component and configured to fix the first side surface to the housing, and a cover component detachably attached to the opening and configured to cover the opening, wherein the cover component includes an elastic member configured to exert force to the vicinity of the second side surface.

The object and advantages of the invention will be realized and attained by means of the elements and combinations particularly pointed out in the claims.

It is to be understood that both the foregoing generation description and the followed detailed description are exemplary and explanatory and are not restrictive of the invention, as claimed.

### BRIEF DESCRIPTION OF DRAWINGS

FIG. 1 is a perspective view illustrating an example of an electronic device (notebook PC) in an open state according to an embodiment of the present invention;

FIG. 2 is a left side perspective view illustrating the electronic device of FIG. 1;

FIG. 3 is a right side perspective view illustrating the electronic device of FIG. 1;

FIG. 4 is a perspective view illustrating the electronic device according to an embodiment of the present invention in a state where the electronic device of FIG. 1 is closed;

FIG. 5 is a perspective view illustrating a bottom surface of a main body unit in a state where the electronic device of FIG. 1 is closed;

FIG. 6 is a perspective view illustrating an exploded state of a main body unit according to an embodiment of the present invention;

FIG. 7 is a schematic diagram illustrating an example of an inner surface of a lid that covers an installing part according to an embodiment of the present invention;

FIG. 8 is a perspective view illustrating a bottom surface of an HDD in a state where the bottom surface of the HDD is faced upward according to an embodiment of the present invention;

FIG. 9 is a perspective view illustrating a top surface of an HDD in a state where the top surface of the HDD 60 is faced upward according to an embodiment of the present invention;

FIG. 10 is a schematic diagram illustrating an HDD in a state installed in an installing part of a main body unit prior to having a connector coupled to another connector according to an embodiment of the present invention;

FIG. 11 is a schematic diagram illustrating an HDD in a final installed state according to an embodiment of the present invention;

FIGS. 12 and 13 are schematic diagrams illustrating a state where both a lid for covering an installing part and a lid for covering a memory substrate installing part are removed according to an embodiment of the present invention;

FIG. 14 is a schematic diagram illustrating a state where a memory substrate is removed from the state illustrated in FIG. 13;

FIG. 15 is a schematic diagram illustrating a main substrate taking up a large portion of space inside a housing according to an embodiment of the present invention;

FIG. 16 is a bottom view of a main body unit according to an embodiment of the present invention;

FIG. 17 is a cross-sectional view taken along line A-A of FIG. 16;

FIG. 18 is an enlarged perspective view illustrating a part of a top surface of a main body unit of the electronic device illustrated in, for example, FIG. 1;

FIG. 19 is a perspective view illustrating an inner surface of a top surface cover of a housing according to an embodiment of the present invention;

FIG. 20 is an enlarged perspective view illustrating a portion of a top surface cover according to an embodiment of the present invention; and

FIG. 21 is a schematic diagram illustrating a second sensor surface 80B of the sensor substrate 80 according to an embodiment of the present invention.

### DESCRIPTION OF EMBODIMENTS

Embodiments of an electronic device are described with an example of a notebook PC.

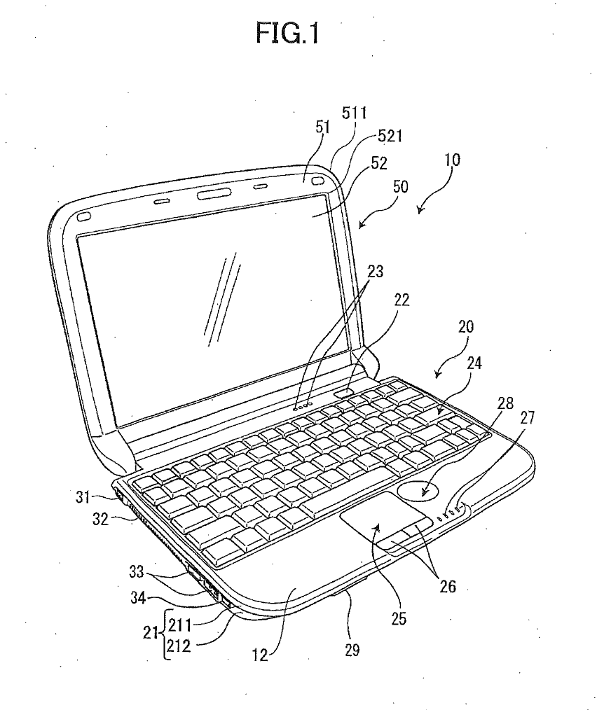

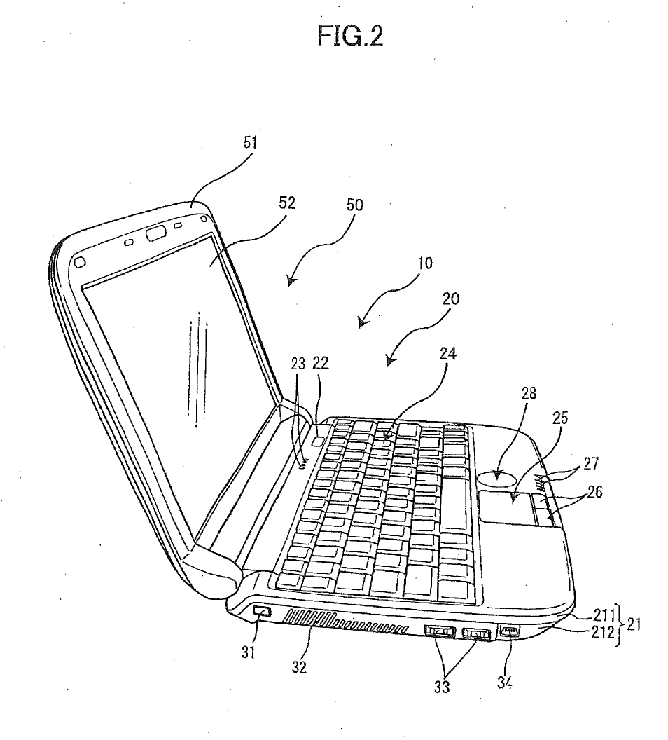

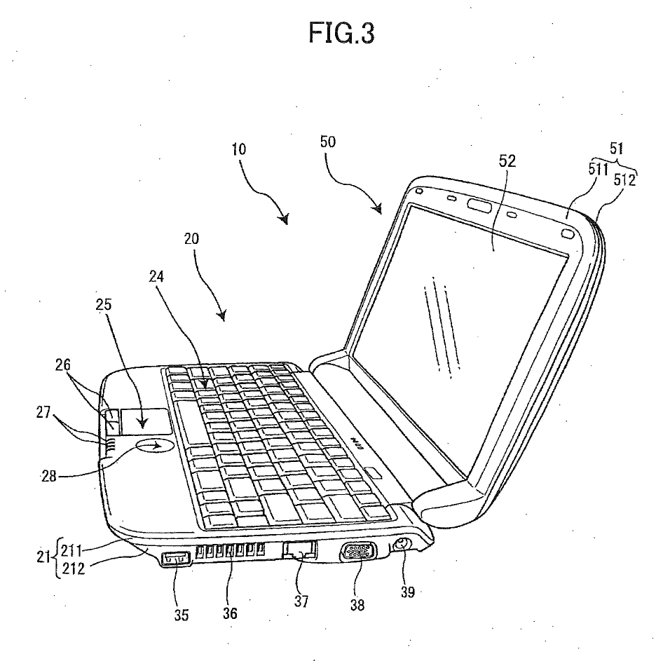

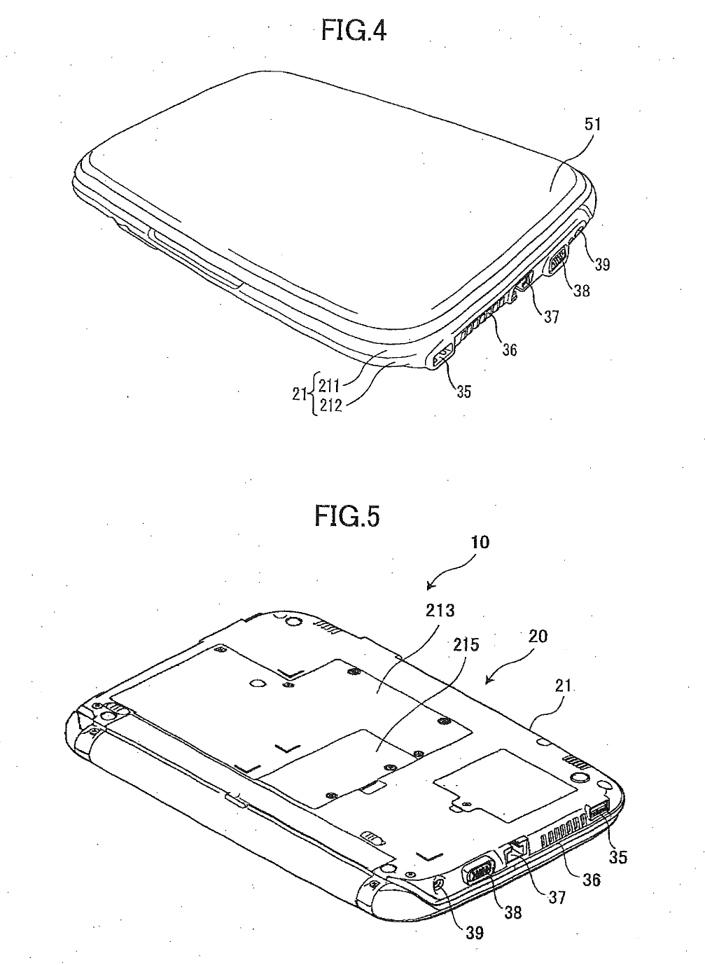

FIG. 1 is a perspective view illustrating an electronic device (in this example, a notebook PC) 10 according to an embodiment of the present invention in a state where the notebook PC 10 is open. FIG. 2 is a left side perspective view illustrating the notebook PC 10 of FIG. 1. FIG. 3 is a right side perspective view illustrating the notebook PC 10 of FIG. 1. Further, FIG. 4 is a perspective view illustrating the electronic device 10 according to an embodiment of the present invention in a state where the notebook PC 10 is closed.

The notebook PC 10 has a main body unit 20 including a housing (also referred to as “first housing”) 21 and a display unit 50 including a housing (also referred to as “second housing”) 51. The housing 51 of the display unit 50 is attached to the housing 21 of the main body unit 20 with a hinge that allows the display unit 50 to be opened as illustrated in FIGS. 1-3 and closed as illustrated in FIG. 4.

The main body unit 20 has a housing 21 including a top surface cover 211 and a bottom surface cover 212. A power button 22, multiple indicator lamps 23, a keyboard 24, a touch pad 25, left and right push buttons 26, and multiple indicator lamps 27 are arranged on a top surface 12 of the top surface cover 211. By moving, for example, a finger on the touch pad 25, a cursor displayed on the below-described display screen 521 of the display unit 50 moves in correspondence with the movement of the finger on the touch pad 25. The left and right push buttons 26 correspond to a right and left buttons of a typical pointing device (e.g., mouse).

Further, the top surface 12 of the top surface cover 211 has a recess part 28 formed on the right side of the touch pad 25. In this embodiment, the recess part 28 has a circular shape from an upper plan view. The recess part 28 has a curved recess surface that becomes deeper the more toward the center of the circle of the recess part 28. For example, the curved recess surface is shaped as a part of a sphere. By placing the finger on recess part 28 and moving the finger with a circular trajectory along the periphery of the recess part 28, an image displayed on the display screen 521 scrolls upward or downward in correspondence with the movement of the finger.

A card slot 29 into which a memory card (not illustrated) is inserted is provided on a front edge surface of the main body unit 20. A speaker (not illustrated) and a microphone/headphone jack (not illustrated) are provided on the front edge surface of the main body unit 20.

As illustrated in FIG. 2, a security lock hole 31 and an air suction port 32 are formed on a left side surface of the bottom cover 212. Further, the bottom cover 212 also includes a USB (Universal Serial Bus) connector port 33 and a mini-USB connector port 34.

As illustrated in FIG. 3, a USB connector port 35, an exhaust port 36, a LAN (Local Area Network) connector port 37, a CRT (Cathode Ray Tube) connector port 38, and a DC power jack 39 are provided on a right side surface of the bottom cover 212.

The display unit 50 has the housing 51 including a frame-like front cover 511 and a rear cover 512. An LCD (Liquid Crystal Display) device 52 including the display screen 521 is provided in the front cover 511. As illustrated in FIGS. 3 and 4, the rear cover 512, which is provided behind the LCD device 52, covers the rear side of the LCD device 52. It is to be noted that the LCD of the LCD device 52 is an example of a display module according to an embodiment of the present invention.

The display module may be other types of display units such as a PDP (Plasma Display Panel).

It is to be noted that the numbers, types, shapes, or positions of the indicator lamps, connector ports, and holes provided in the main body unit 20 are not limited to those described above and may be changed in accordance with the specifications of an electronic device to be used.

### (Fixing Structure of HDD)

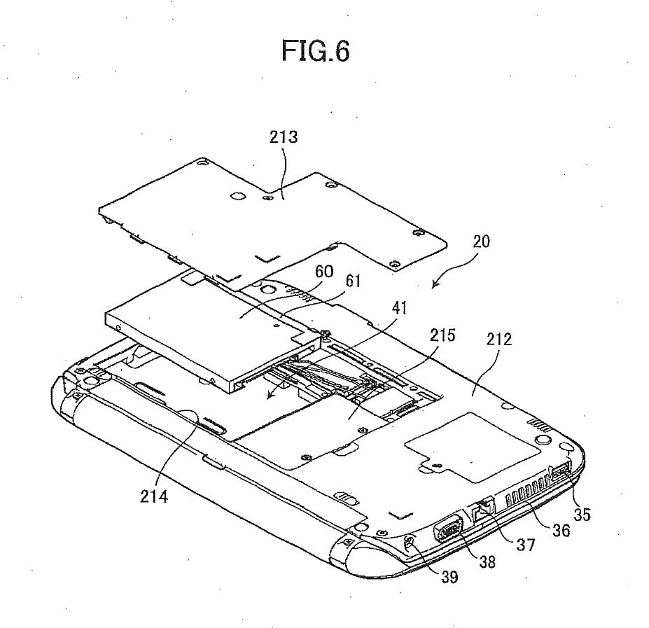

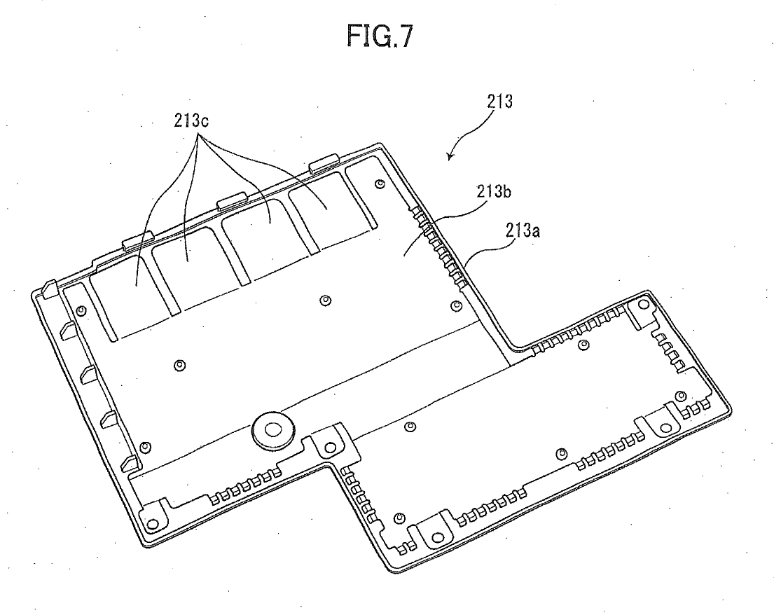

FIG. 5 is a perspective view illustrating a bottom surface of the main body unit 20 in a state where the notebook PC 10 illustrated in FIGS. 1-4 is closed. FIG. 6 is a perspective view illustrating an exploded state of the main body unit 20 according to an embodiment of the present invention.

As illustrated in FIG. 6, an installing part 41 is formed in the main body unit 20. The installing part 41 is for installing an HDD 60 therein. An opening 214 is formed in the bottom surface cover 212 of the housing 21, to thereby expose the installing part 41 toward the bottom surface of the main body unit 20. A lid 213, which is provided at the bottom surface of the bottom surface cover 212, covers the opening 214 as illustrated in FIGS. 5 and 6. FIG. 6 illustrates the lid 213 and the HDD 60 in a state dissembled from the main body unit 20.

An attachment fitting 61 is fixed to the HDD 60. The attachment fitting 61 extends along either one of the left or right sides of the HDD 60. As described in detail below, the HDD 60 is fixed to the housing 21 via the attachment fitting 61.

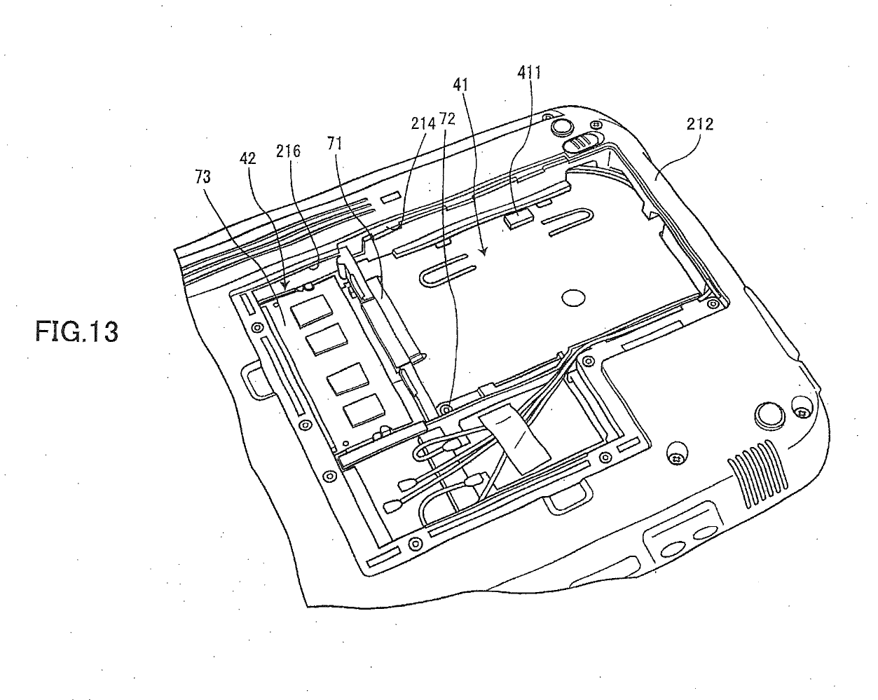

As described in detail below, the main body unit 20 also includes a memory substrate installing part 42 for installing a memory substrate 73 therein. The memory substrate installing part 42 has an opening 216 formed in the bottom surface of the bottom surface cover 212 (see, for example, FIG. 12). FIGS. 5 and 6 illustrate a lid 215 that covers the opening 216.

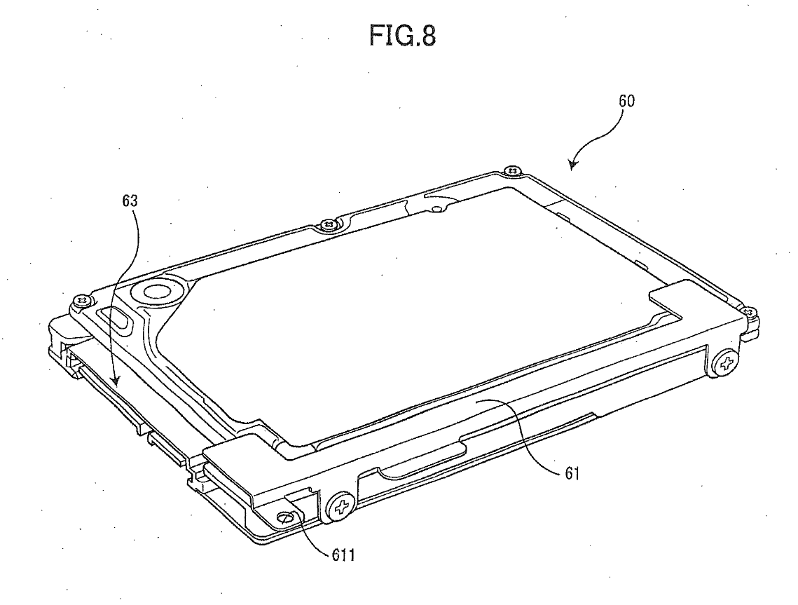

FIG. 7 is a schematic diagram illustrating an example of an inner surface of the lid 213 that covers the installing part 41.

The lid 213 includes a planar-shaped main body 213a and a metal plate 213b. The main body 213a constitutes the bottom surface of the bottom surface cover 212 of the main body unit 20. The metal plate 213b is fixed to an inner surface of the main body 213a. The metal plate 213b acts as a part of a shield that covers a circuit or the like (not illustrated) installed in the main body unit 20.

The lid 213 also includes an elastic member 213c formed by bending a part of the metal plate 213b in a direction separating from the inner surface of the main body 213a. The elastic member 213c is for exerting pressure to the HDD 60.

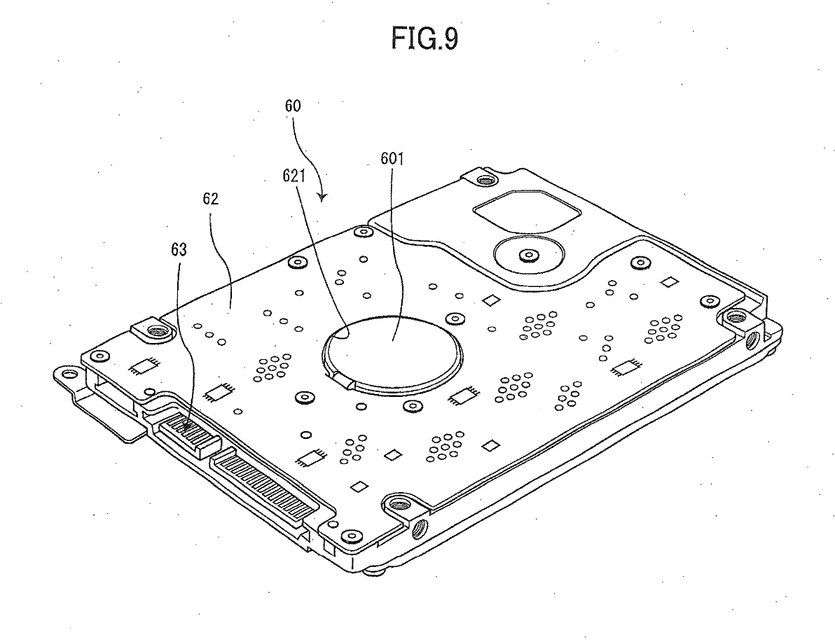

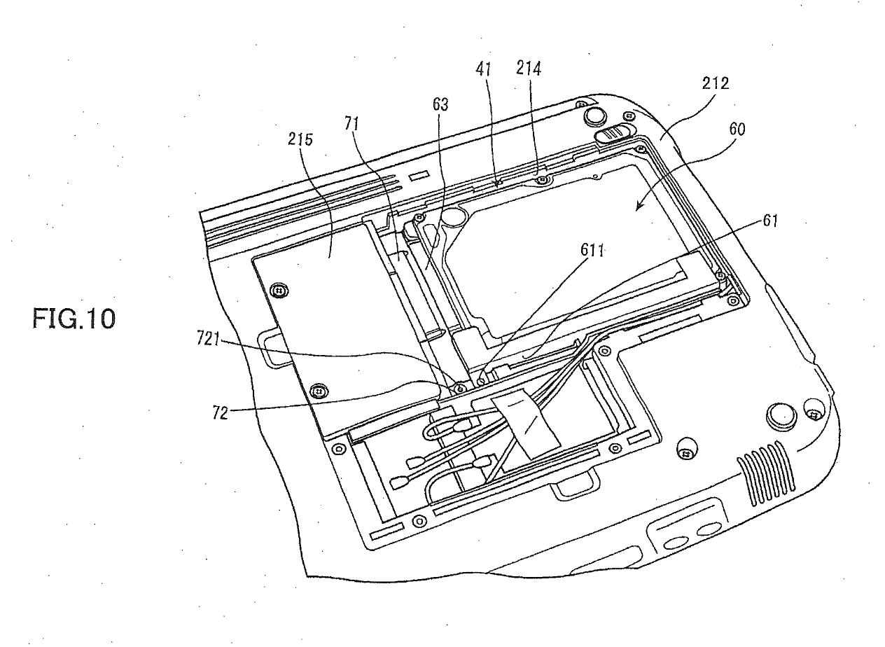

FIG. 8 is a perspective view illustrating an example of a bottom surface of the HDD 60 (i.e. surface of the HDD 60 facing downward to the bottom surface of the main body unit 20) in a state where the bottom surface of the HDD 60 is faced upward. FIG. 9 is a perspective view illustrating an example of a top surface of the HDD 60 (i.e. surface of the HDD 60 facing upward to the top surface of the main body unit 20) in a state where the top surface of the HDD 60 is faced upward.

A control substrate 62 of the HDD 60 is provided in a manner dominating a large portion of the top surface of the HDD 60 (i.e. surface of the HDD 60 facing upward in FIG. 9). The control substrate 62 includes a round hole 621 through which a bottom surface 601 of a motor of the HDD 60 can be seen. The HDD 60 includes a component that is mechanically movable. That is, in this embodiment, the motor of the HDD 60 is configured to rotate a round disk-shaped recording medium (i.e., hard disk (HD)) of the HDD 60. The HDD 60 is a storage device that accesses information along with the mechanical movement of the movable component.

Further, a connector 63 is mounted to the front end of the HDD 60 as illustrated in FIG. 9. The connector 63 is for transmitting/receiving data between the HDD 60 and an external communication device. The connector 63 may also be used for receiving electric power supplied from an external power supply device.

Further, the HDD 60 has a first side surface and a second side surface provided on the opposite side of the first side surface. The first and second side surfaces extend in a longitudinal direction of the HDD 60. In the embodiment illustrated in FIG. 8, the HDD 60 has an attachment fitting 61 extending along the first side surface of the HDD 60. The attachment fitting 61 is fastened to the first side surface of the HDD 60 with screws. The attachment fitting 61 has a fastening hole 611 provided at a part toward the front end side of the HDD 60. In a state where the HDD 60 is installed in the installing part 41 of the main body unit 60 (see, for example, FIG. 6), the HDD 60 is fixed to the main body unit 60 by fastening a screw to the fastening hole 611. In this embodiment, the HDD 60 is fastened to the inside of the main body unit only at the fastening hole 611.

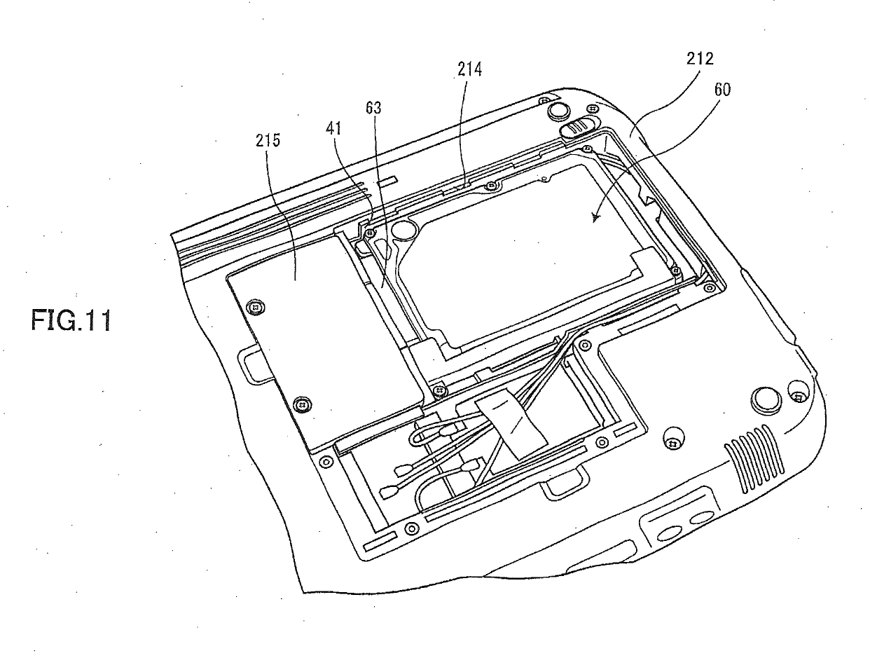

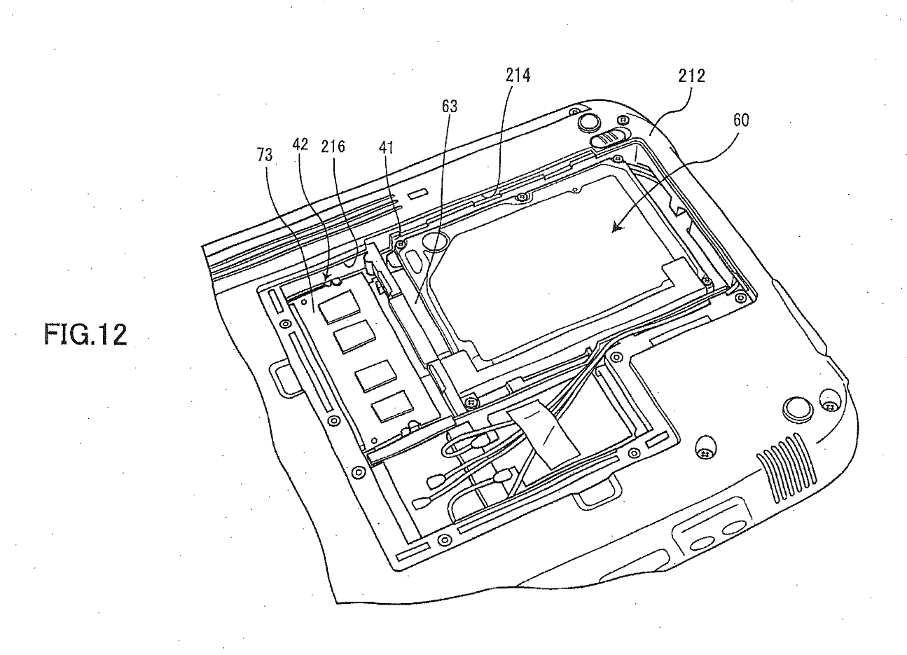

FIG. 10 is a schematic diagram illustrating an embodiment of the HDD 60 in a state installed in the installing part 41 of the main body unit 60 prior to having the connector 63 coupled to the below-described connector 71. FIG. 11 is a schematic diagram illustrating an embodiment of the HDD 60 in a final installed state.

After the HDD 60 is placed inside the installing part 41, the HDD 60 is slid forward (i.e. toward the direction of the connector 71 provided on the below-described main substrate 70), so that the connector 63 is coupled to the connector 71 provided on the main substrate 70. By sliding the HDD 60 in such manner, the connectors 63 and 71 are coupled together and the fastening hole 611 of the attachment fitting 61 is moved to a position superposing a screw hole 721 formed at a center of a boss 72 of a member fixed to the housing 21. In such state, the attachment fitting 61 is fixed to the main body unit 20 by fastening a screw to the fastening hole 611 and the screw hole 721 as illustrated in FIG. 11.

FIGS. 12 and 13 are schematic diagrams illustrating a state where both the lid 213 for covering the installing part 41 and the lid 215 for covering the memory substrate installing part 24 are removed. It is to be noted that FIG. 12 illustrates a state where the HDD 60 is installed in the installing part 41 whereas the FIG. 13 illustrates a state where the HDD 60 is removed.

As illustrated in FIGS. 12 and 13, the memory substrate 73 installed in the memory substrate installing part 42 becomes exposed when the lid 215 is removed (see also, for example, FIGS. 6, 10, and 11). A memory chip is mounted on the memory substrate 73. According to necessity, the memory chip can be replaced with another memory chip having a different storage capacity.

As illustrated in FIG. 13, a rubber plate 411 for receiving the top surface of the HDD 60 is placed in the installing part 41. The rubber plate 411 serves to alleviate vibration transmitted to the HDD 60.

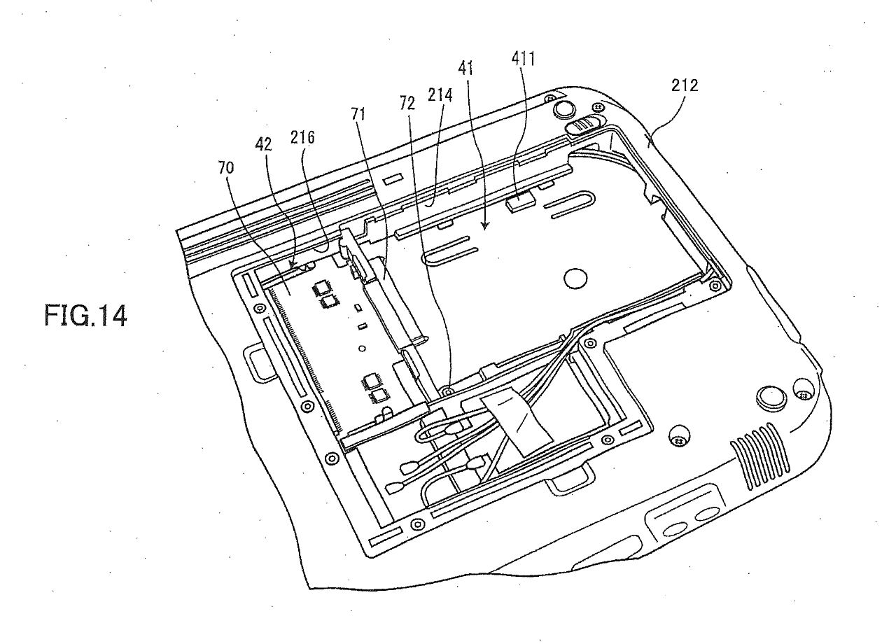

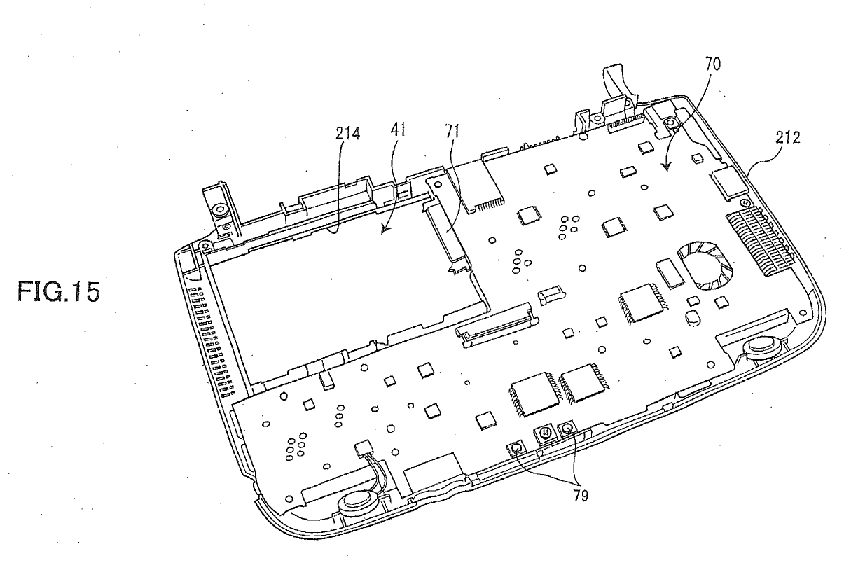

FIG. 14 is a schematic diagram illustrating a state where the memory substrate 73 is removed from the state illustrated in FIG. 13. FIG. 15 is a schematic diagram illustrating the main substrate 70 installed inside the housing 21. FIG. 15 illustrates the main body unit 60 being flipped upside down from the state illustrated in FIG. 14. In FIG. 15, the top surface cover 211 and the keyboard 24 are removed from the main body unit 20, so that the main substrate 70 underneath the top surface cover 211 and the keyboard 24 can be illustrated.

The memory substrate 73 illustrated in FIG. 13 is arranged in a manner superposing the main substrate 70. In FIG. 13, a portion of the main substrate 70 provided behind the memory substrate 73 can be viewed by removing the memory substrate 73. As illustrated in FIG. 15, the main substrate 70 extends inside the housing 21. An electronic circuit and circuit elements are mounted on the main substrate 70 for performing, for example, computation with the CPU or controlling of the display screen 521 (see FIG. 1). The connector 71 is mounted to the main substrate 70 in a manner projecting toward the installing part 41. As illustrated in, for example, FIG. 10, the connector 71 is coupled to the connector 63 of the HDD 60.

In this embodiment, two switches 79 are mounted on the main substrate 70. Each of the switches 79 can be turned on by receiving force exerted from corresponding push buttons 26 (see, for example, FIG. 1). With the switches 79, the depressing of the push buttons 26 can be detected.

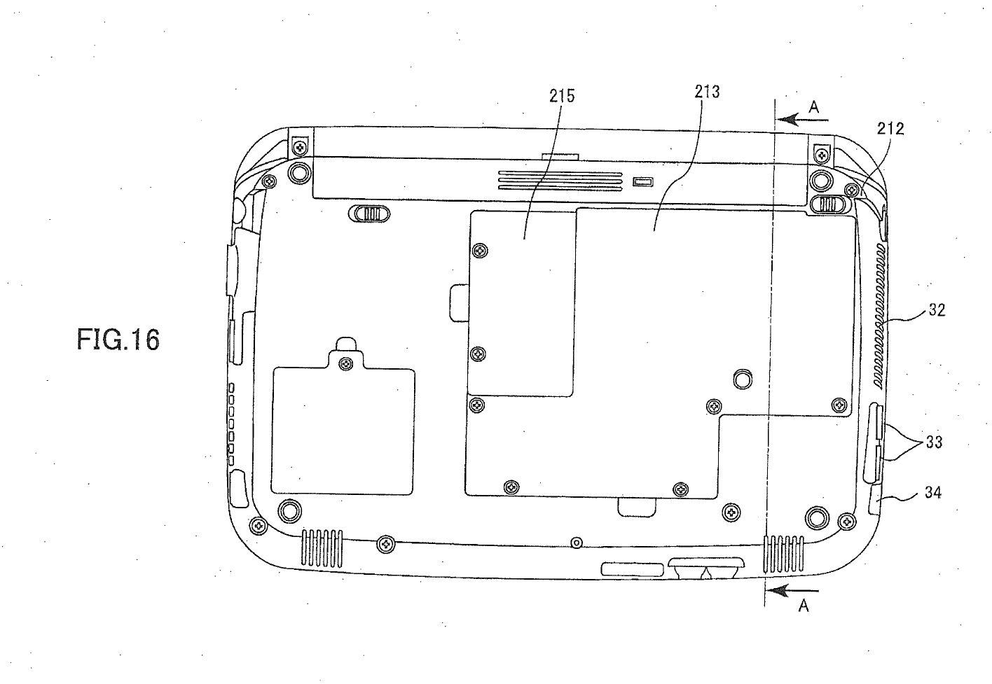

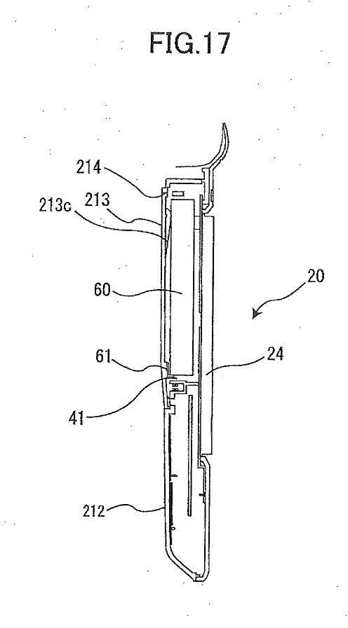

FIG. 16 is a bottom view of the main body unit 20 according to an embodiment of the present invention. FIG. 17 is a cross-sectional view taken along line A-A of FIG. 16.

As described above, in a state where the HDD 60 is installed in the installing part 41, the attachment fitting 61 provided along the first side surface of the HDD 60 is fastened to the inside of the main body unit 20 with a screw (see, for example, FIGS. 10 and 11).

As described above, the metal plate 213b is fixed to the inner surface of the lid 213 (see, for example, FIG. 7). The lid 213 can be detachably attached to the opening 214 of the installing part 41. The lid 213 also includes the elastic member 213c formed by bending a part of the metal plate 213b inward toward the HDD 60. The elastic member 213c exerts force to the vicinity of the second side surface of the HDD 60 located on the opposite of the first side surface and facing an inner wall of the opening 214. Thereby, a part of the HDD 60 toward the second side surface is sandwiched between the elastic member 213c and the rubber plate 411 placed in the installing part 41.

Accordingly, with the above-described embodiment, only either one of the first and second side surfaces of the HDD 60 is fixed to the main body unit 20 via the attachment fitting 61. In the above-described embodiment, even without using an attachment fitting on the side of the second side surface of the HDD 60, the HDD 60 can be steadily maintained inside the installing part 41 by force exerted from the elastic member 213c formed by bending the metal plate 213 (inner surface of the lid 213 serving as a shield) to the vicinity of the second side surface. Because the attachment fitting 61 is only provided on the first side surface, the size of the installing part 41 and the number of manufacturing steps can be reduced. This also contributes to the reduction of the entire weight of the notebook PC 10.

Although the attachment fitting 61 of the above-described embodiment is attached in a manner extending along the entire first side surface of the HDD 60, the attachment fitting 61 may alternatively be constituted with two components in which one component is attached to a front end part of the first side surface and the other component is attached to a rear end part of the first side surface. In this case, each of the two components of the attachment fitting 61 is fastened to the main body unit 20.

The rubber plate 411 is not limited to the short piece illustrated in FIG. 14. For example, the rubber plate 411 may have substantially the same length as the second side surface of the HDD 60, so that the rubber plate 411 extends along the side surface of the HDD 60. Alternatively, the rubber plate 411 may be a sheet covering the entire bottom surface of the installing part 41.

Further, although the HDD 60 is described as the electronic component to be installed in the installing part 41, other electronic components may be installed. For example, a Solid State Drive (SSD) may be installed in the installing part 41.

### (Scroll Pad Configuration)

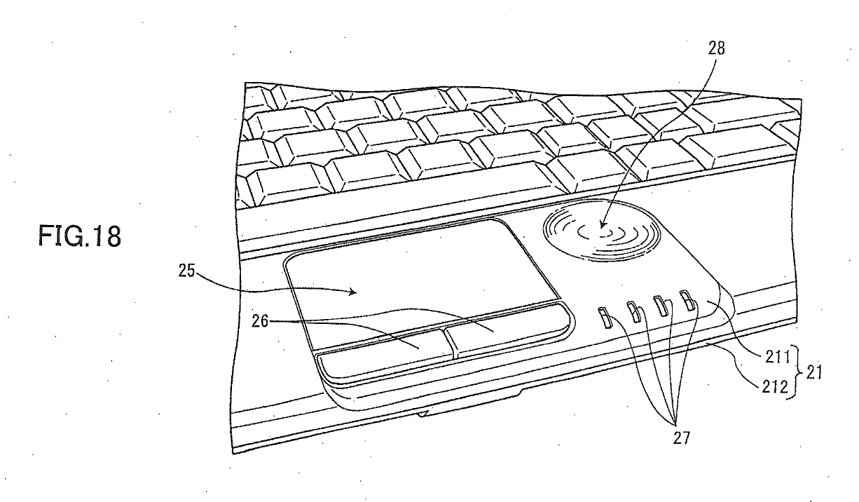

FIG. 18 is an enlarged perspective view illustrating a part of the top surface 12 of the main body unit 20 of the notebook PC 10 illustrated in, for example, FIG. 1.

As described above with reference to FIG. 1, the touch pad 25 and the left and right push-buttons 26 are arranged on a front side of the top surface 12 of the top surface cover 211. Further, the top surface 12 of the top surface cover 211 has the recess part 28 formed on the right side of the touch pad 25. The recess part 28 has a circular shape from an upper plan view. The recess part 28 has a curved recess surface that becomes deeper the more toward the center of the circle of the recess part 28. The curved recess surface is shaped as a part of a sphere.

The recess part 28 is used as an element for performing a scroll operation. By operating the recess part 28, an image displayed on the display screen 521 (see, for example, FIG. 1) can be scrolled.

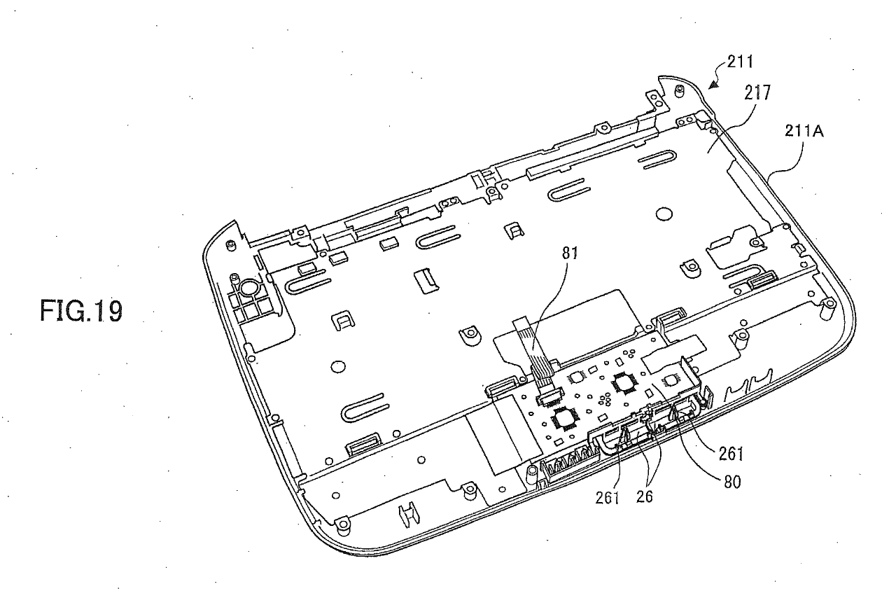

FIG. 19 is a perspective view illustrating an inner surface 211A of the top surface cover 211 of the housing 21 according to an embodiment of the present invention.

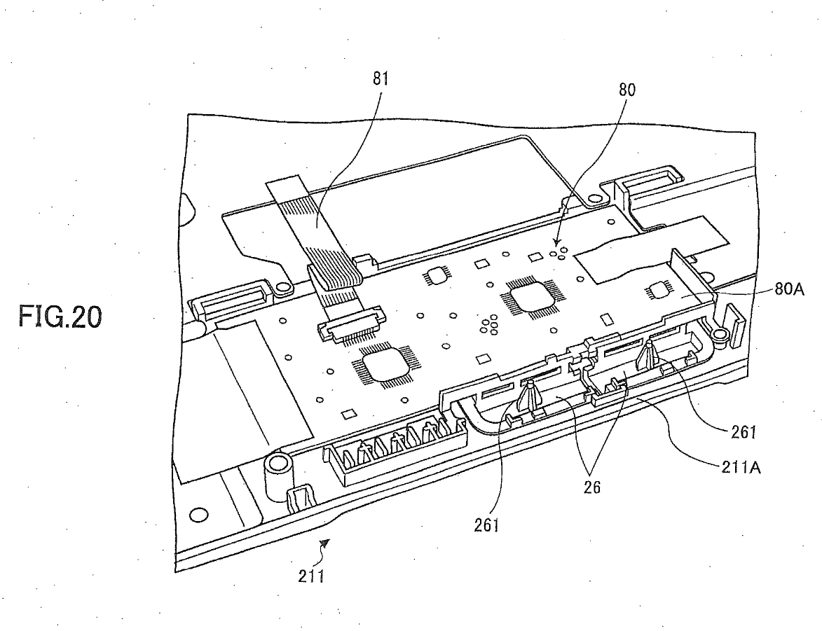

FIG. 20 is an enlarged perspective view illustrating a portion of the top surface cover 211.

A metal plate 217 is provided on the inner surface 211A of the top surface cover 211 in a manner taking up a large portion of the inner surface 211A of the top surface cover 211. Further, a sensor substrate 80 is fixed to the inner surface 211A of the top surface cover 211. The sensor substrate 80 has a first sensor surface 80A including an area that can encompass the touch pad 25 and the recess part 28 (see, for example, FIG. 18). Thus, the sensor substrate 80 is formed covering the rear surfaces of the touch pad 25 and the recess part 28.

The inner surface 211A of the top surface cover 211 includes the inner surfaces of the left and right push buttons 26. Protrusions 261 are provided on the rear surfaces of the left and right push buttons 26. When the left and/or right push buttons 26 are pressed, corresponding switches 79 mounted on the main substrate 70 are pressed by corresponding protrusions 261. Thereby, the depression of the left and/or right push buttons 26 is detected.

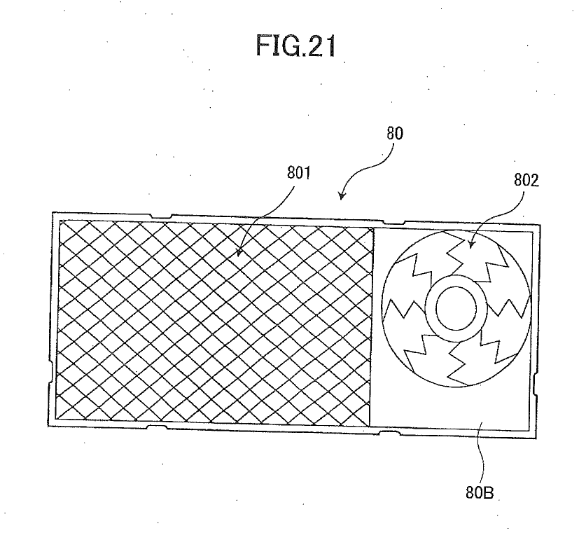

FIG. 21 is a schematic diagram illustrating a second sensor surface 80B of the sensor substrate 80 according to an embodiment of the present invention.

As illustrated in FIG. 21, the second sensor surface 80B is a surface formed on the other side of the first sensor surface 80A illustrated in FIGS. 19 and 20. Multiple electrostatic sensors are arranged on the second sensor surface 80B. The second sensor surface 80B has multiple rectangular electrostatic sensors arranged two-dimensionally on a first area 801 thereof. Further, the second sensor surface 80B has multiple electrostatic sensors arranged in a circle on a second area 802 thereof.

In the state where the second sensor surface 80B illustrated in FIG. 21 is facing upward (i.e. toward the inner surface 211A of the top cover 211), the sensor substrate 80 is fixed to the inner surface 211A of the top cover 211 in a manner that the first area 801 and the second area 802 are positioned in correspondence with the rear surface of the touch pad 25 and the recess part 28, respectively. When a finger contacts or moved close to the touch pad 25 or the recess part 28, the sensor substrate 80 detects changes of electrostatic capacity corresponding to the contact or movement of the finger.

For example, in a case where a finger contacts the touch pad 25 and is moved in a given direction on the touch pad 25, a first electrostatic sensor provided in the first area 801 of the sensor substrate 80 detects the direction of the movement of the finger. In a case where a finger contacts the recess part 28 and is moved to draw a circular trajectory, a second electrostatic sensor provided in the second area 802 detects the direction of the movement of the finger.

The sensor substrate 80 is connected to the main substrate 70 (see, for example, FIG. 15) via a flat cable 81 (see, for example, FIGS. 19 and 20). The detection results of the sensor substrate 80 are transmitted from the sensor substrate 80 to the main substrate 70 via the flat cable 81. The main substrate 70 also serves as a control part that controls the displaying of an image or a cursor on the display screen 521. That is, the main substrate 70 controls the displaying of an image or a cursor on the display screen 521 in accordance with the detection results from the sensor substrate 80. For example, in a case where a finger contacts the touch pad 25 and is moved on the touch pad 25, the main substrate 70 moves a cursor displayed on the display screen 521 in correspondence with the movement of the finger on the touch pad 25. Further, in a case where a finger contacts the recess part 28 and is moved to draw a circular trajectory, the main substrate 70 scrolls an image displayed on the display screen 521 in correspondence with the movement of the finger on the recess part 28.

As described above, the recess part 28 has a gradually curving recess surface that is shaped as a part of a sphere. In addition to providing an excellent design, the shape of the recess part 28 also improves operability where the finger is moved in a manner drawing a circular trajectory.

In the above-described embodiments, the recess part 28 is formed on the right side of the touch pad 25. Alternatively, the recess part 28 may be formed on the left side of the touch pad 25 or a position that does not obstruct operation of the keyboard 24.

In the above-described embodiments, the notebook PC 10 is described as an example of the electronic device according to an embodiment of the present invention. However, an electronic device other than the notebook PC may also be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a housing including an installing part having an opening;
an electronic component installed in the installing part and including a first side surface and a second side surface;
an attachment component fastened to the electronic component and configured to fix the first side surface to the housing; and
a cover component detachably attached to the opening and configured to cover the opening;
wherein the cover component includes an elastic member configured to exert force to the vicinity of the second side surface.

2. The electronic device as claimed in claim 1, wherein the attachment component extends along the first side surface of the electronic component.

3. The electronic device as claimed in claim 1,
wherein the cover component further includes
a plate component constituting an outer surface of the electronic device, and
a metal plate fixed to an inner surface of the plate component;
wherein the elastic member is formed from a part of the metal plate.

4. The electronic device as claimed in claim 1, further comprising:
a first connector mounted to the electronic component; and
a substrate installed inside the housing and including a second connector that engages the first connector in a state where the electronic component is installed in the installing part.

5. The electronic device as claimed in claim 1,
wherein the electronic component includes a storage device having a movable part;
wherein the storage device is configured to access information along with a mechanical movement of the movable component.

6. The electronic device as claimed in claim 1,
wherein the attachment component includes a fastening hole;
wherein the housing includes a screw hole;
wherein the housing and the attachment component are fastened to each other at the fastening hole and the screw hole by a screw.

7. The electronic device as claimed in claim 1,
wherein the housing includes first and second housings;
wherein the first housing has an electronic circuit installed therein and a top surface on which a keyboard is mounted;
wherein the second housing includes a display screen;
wherein the first housing and second housing are attached to each other with a hinge.
